(19) United States
(12) Patent Application Publication
(10) Pub. No.: US 2003/0084220 A1
(43) Pub. Date: May 1, 2003

(54) Active adapter chip for use in a flash card reader

(76) Inventors: Larry Lawson Jones, Palo Alto, CA (US); Sreenath Mambakkam, San Jose, CA (US); Arockiyaswamy Venkidu, Menlo Park, CA (US)

Correspondence Address: Joseph A. Sawyer, Jr., SAWYER LAW GROUP LLP, P.O. Box 51418, Palo Alto, CA, 94303, US

(21) Appl. No.: 10/002,567

(22) Filed: Nov. 1, 2001

(51) Int. Cl. H05K 7/10; G06F 13/00

(52) U.S. Cl. 710/301

(57) ABSTRACT

A multi-flash-card reader is disclosed. The multi-flash-card reader comprises an active adapter chip for converting multiple flash-card interfaces to a plurality of output interfaces for a device. The multiple flash-card interfaces include a CompactFlash interface and smaller interfaces having fewer pins that the CompactFlash interface. The reader includes a CompactFlash connector, coupled to the active adapter chip, for receiving a CompactFlash card through a single slot in the single slot multi-flash-card reader. The CompactFlash connector makes electrical connection with the CompactFlash card for signals in the CompactFlash interface. The reader also includes an adapter, having a physical shape to removably insert into the CompactFlash connector. The adapter has a mating CompactFlash connector that fits the CompactFlash connector. The adapter also has a smaller connector. The smaller connector is for fitting to other flash-memory cards having the smaller interfaces. The reader also includes wiring means, in the adapter, connected between the smaller connector and the mating CompactFlash connector, for directly connecting signals from the smaller connector in the smaller interface with signals in the mating CompactFlash connector. The adapter allows the other flash-memory cards having the smaller interfaces to fit into the CompactFlash connector through the single slot to be read by the active adapter chip. An active adapter chip for flash-memory cards in accordance with the present invention accepts cards of several different formats. The active adapter chip accepts SmartMedia, MultiMediaCard, Secure Digital, and Memory Stick cards. The active adapter chip is constructed using the CompactFlash card form factor. A reader that reads CompactFlash cards can then read any of the other flash-memory cards that plug into the CompactFlash adapter.

### FIELD OF THE INVENTION

The present invention relates generally to flash memory readers, and more particularly for interfacing several different types of flash memory cards to a personal computer.

### BACKGROUND OF THE INVENTION

Digital cameras have become one of the most popular of electronic devices. In a recent year, more digital cameras were sold than traditional film cameras. Images from digital cameras can be downloaded and stored on personal computers. Digital pictures can be converted to common formats such as JPEG and sent as e-mail attachments or posted to virtual photo albums on the Internet. Video as well as still images can be captured, depending on the kind of digital camera.

Digital cameras typically capture images electronically and ultimately store the images as bits (ones and zeros) on a solid-state memory. Flash memory is the most common storage for digital cameras. Flash memory contains one or more electrically-erasable read-only-memory (EEPROM) integrated circuit chips that allow reading, writing, and block erasing.

Early digital cameras required the user to download or transfer the images from the flash memory within the digital camera to a personal computer (PC). A standard serial cable was most widely used. However, the limited transfer rate of the serial cable and the large size of the digital images made such serial downloads a patience-building experience. Serial downloads could easily take half an hour for only a few dozen images.

Digital camera manufacturers solved this problem by placing the flash memory chips on a small removable card. The flash-memory card could then be removed from the digital camera, much as film is removed from a standard camera. The flash-memory card could then be inserted into an appropriate slot in a PC, and the image files directly copied to the PC.

FIG. 1A shows a flash memory card and adapter for transferring images from a digital camera to a PC. A user takes pictures with digital camera 14 that are stored in image files on flash memory chip(s). The flash memory chip is contained in CompactFlash card 16, which can be removed from digital camera 14 by pressing a card-eject button. Thus CompactFlash card 16 contains the image files.

While some smaller hand-held computers or personal-digital-assistants (PDA) have slots that receive CompactFlash cards, most PC's do not. Laptop or notebook PC's have PC-card (earlier known as PCMCIA, Personal Computer Memory Card International Association) slots that can receive PCMCIA cards. Many functions have been placed on PCMCIA cards, such as modems, Ethernet, flash memory, encryption keys, and even miniature hard drives.

CF-to-PCMCIA adapter 10 is a passive adapter that contains an opening that receives CompactFlash card 16. FIG. 1B shows CF-to-PCMCIA adapter 10 with CompactFlash card 16 inserted. Such CF-to-PCMCIA adapters 10 sell for as little as $5-10. CompactFlash is a trademark of SanDisk Corp. of Sunnyvale, Calif.

FIG. 1C shows a PC connected to a PCMCIA reader. Most laptop and notebook PC's contain one or two PCMCIA slots 22 that CF-to-PCMCIA adapter 10 can fit into. Then the user merely has to copy the image files from CompactFlash card 16 to the hard disk of PC 20. Since high-speed parallel buses are used, transfer is rapid, about the same speed as accessing the hard disk. Thus a half-hour serial-cable transfer can be reduced to less than a minute with the $5 CF-to-PCMCIA adapter.

Desktop PC's usually do not have PCMCIA slots. Then PCMCIA reader 12 can be used. PCMCIA reader 12 accepts CF-to-PCMCIA adapter 10 and connects to PC 20 through a parallel or high-speed Universal Serial Bus (USB) cable.

Multiple Flash-Card Formats

Although the CompactFlash card format is relatively small, being not much more than an inch square, other smaller cards have recently emerged. FIG. 2A illustrates various formats of flash-memory cards used with digital cameras. Many digital cameras still use CompactFlash card 16, which can be inserted into CF-to-PCMCIA adapter 10 for transfer to a PC. Other smaller, thinner formats have emerged and are used with some manufacturer's digital cameras. For example, SmartMedia card 24 is less than half an inch long, yet has enough flash memory capacity for dozens of images. SmartMedia-to-PCMCIA adapter 10′ is available commercially for about $60. The higher cost is believed to be due to a converter chip within adapter 10′. Also, different adapters 10′ are required for different memory capacities of SmartMedia card 24. SmartMedia is a trademark of the SSFDC Forum of Tokyo, Japan.

Other kinds of flash-memory cards that are being championed by different manufacturers include MultiMediaCard (MMC) 28 and the related Secure Digital Card (SD) 26. MMC is controlled by MultiMediaCard Assiociation that includes SanDisk Corp., Infineon Technologies, and others while SD is controlled by the SD Group that includes Matsushita Electric Industrial Co., SanDisk Corporation and Toshiba Corp, among others. Another emerging form factor from SONY is Memory Stick 18. Memory Stick has a PCMCIA/Floppy adapter while MMC has a floppy adapter.

The different physical shapes and pin arrangements of cards 24, 26, 28 and Memory Stick 18 prevent their use in CF-to-PCMCIA adapter 10. Indeed, most of these cards 24, 26, 28 have less than a dozen pins, while CompactFlash card 16 has a larger 50-pin interface. Furthermore, serial data interfaces are used in the smaller cards 24, 26, 28 while a parallel data bus is used with CompactFlash card 16.

FIG. 2B shows a Memory Stick-to-PCMCIA adapter using an active converter chip. Memory Stick 18 fits into an opening in Memory Stick-to-PCMCIA adapter 15, allowing adapter 15 and the Memory Stick to be plugged into a standard PCMCIA slot on a PC. However, adapter 15 has an integrated circuit (IC) converter chip 11 within it. Converter chip 11 may be needed to convert the serial data format of Memory Stick 18 to the parallel data format of a 68-pin PCMCIA slot. Inclusion of converter chip 11 in adapter 15 significantly increases the cost and complexity of adapter 15 compared to CF-to-PCMCIA adapter 10 which is a passive adapter without a converter chip.

While the advances in flash-memory card technology are useful, the many different card formats present a confusing array of interface requirements to a PC. Different adapters are needed for each of the card formats. PCMCIA card reader 12 can be replaced with other format readers, such as a SmartMedia Card reader, and even some multi-standard readers are available, such as a universal reader from Lexar Media that reads CompactFlash or SmartMedia in addition to PCMCIA.

The PCMCIA card interface (68-pins) has been around for a number of years and has been used extensively as an expansion slot for notebooks and other mobile computing devices. It is envisaged to use this popular interface to connect various devices such as SmartMedia, Memory Stick, MultimediaCard, Secure Digital card, Memory Stick V2 (also called the Duo), USB expansion slot, etc., to a computing system, printer, PDA or other system, which has a mating 68 pin connector.

When such adapters (68-pin or any other pin/interface based adapter) are used to interchangeably connect to the computing system, a method of storing these adapters near the slot is desired (see FIG. 1).

FIG. 2C illustrates a conventional bay 100 for storing the adapters (front view). The bay 100 includes an interface port 102 and slots 102, 104 and 106 for storing adapters. The interface port 102 is the port to which dissimilar interfaces are connected via adapters. For example, a CompactFlash (or PCMCIA) interface can connect to a computing system, acting as the interface port to which other interfaces such as SmartMedia, Memory Stick, Duo, USB, 1394, etc., can use adapters. The storage bay keeps all the adapters together.

In this type of bay, the upper slots are mounted right side up but the bottom slots require user to invert the media before inserting it into the slot. Since the slots are mounted on either side of a PCB (printed circuit board) the bottom slots are also very difficult to access. A new adapter for the upcoming smaller footprint Memory Stick (also called the Duo) is desired to as to mate it with 68-pin PCMCIA interface or 50pin CompactFlash interface or any other similar interface. Therefore it is desirable to have a scheme wherein:

1. All slots are designed such that the flash media can be inserted face up into each slot.

2. There is comfortable separation space between the upper and lower row of slots.

Therefore, what is desired is an active adapter which can be used for interchangeably connecting a different memory/memories to a device. For example, such a device could be a printer, a PDA device, or other device which includes a slot for accepting a connector for a CompactFlash disk. It is known, for example, that many printers have a connector for a CompactFlash. Accordingly, what is needed is an active adapter which addresses the above-identified problems. The present invention addresses such a need.

### SUMMARY OF THE INVENTION

A multi-flash-card reader is disclosed. The multi-flash-card reader comprises an active adapter chip for converting multiple flash-card interfaces to a plurality of output interfaces for a device. The multiple flash-card interfaces include a CompactFlash interface and smaller interfaces having fewer pins that the CompactFlash interface. The reader includes a CompactFlash connector, coupled to the active adapter chip, for receiving a CompactFlash card through a single slot in the single slot multi-flash-card reader. The CompactFlash connector makes electrical connection with the CompactFlash card for signals in the CompactFlash interface.

The reader also includes an adapter, having a physical shape to removably insert into the CompactFlash connector. The adapter has a mating CompactFlash connector that fits the CompactFlash connector. The adapter also has a smaller connector. The smaller connector is for fitting to other flash-memory cards having the smaller interfaces.

The reader also includes wiring means, in the adapter, connected between the smaller connector and the mating CompactFlash connector, for directly connecting signals from the smaller connector in the smaller interface with signals in the mating CompactFlash connector. The adapter allows the other flash-memory cards having the smaller interfaces to fit into the CompactFlash connector through the single slot to be read by the active adapter chip.

An active adapter chip for flash-memory cards in accordance with the present invention accepts cards of several different formats. The active adapter chip accepts SmartMedia, MultiMediaCard, Secure Digital, and Memory Stick cards. The active adapter chip is constructed using the CompactFlash card form factor. A reader that reads CompactFlash cards can then read any of the other flash-memory cards that plug into the CompactFlash adapter.

### BRIEF DESCRIPTION OF THE DRAWINGS

FIG. 1A shows a flash memory card and adapter for transferring images from a digital camera to a PC.

FIG. 1B shows a CF-to-PCMCIA adapter with CompactFlash card inserted.

FIG. 1C shows a PC connected to a PCMCIA reader.

FIG. 2A illustrates various formats of flash memory cards used with digital cameras.

FIG. 2B shows a Memory Stick-to-PCMCIA adapter using an active converter chip.

FIG. 2C illustrates a conventional bay for storing the adapters.

FIG. 3A shows a universal CompactFlash adapter that accepts SmartMedia, MultiMediaCard, Secure Digital and Memory Stick flash-memory cards.

FIG. 3B shows a CompactFlash reader that reads SmartMedia, MultiMediaCard, Secure Digital, and Memory Stick flash-memory cards on the input side to the CompactFlash form factor and interfaces to CompactFlash, IDE and PCMCIA on an output side.

FIG. 3C is a table showing a translator in accordance with the present invention.

FIG. 4 is a block diagram of the active adapter in accordance with the present invention.

FIG. 5 is a table of pin mappings for the SmartMedia, MMC/SD and Memory Stock to CompactFlash adapters.

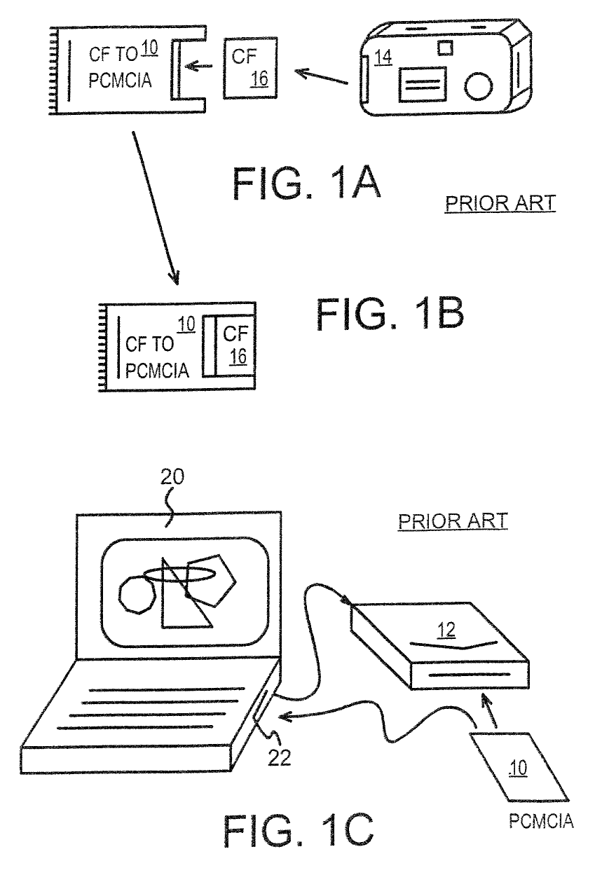

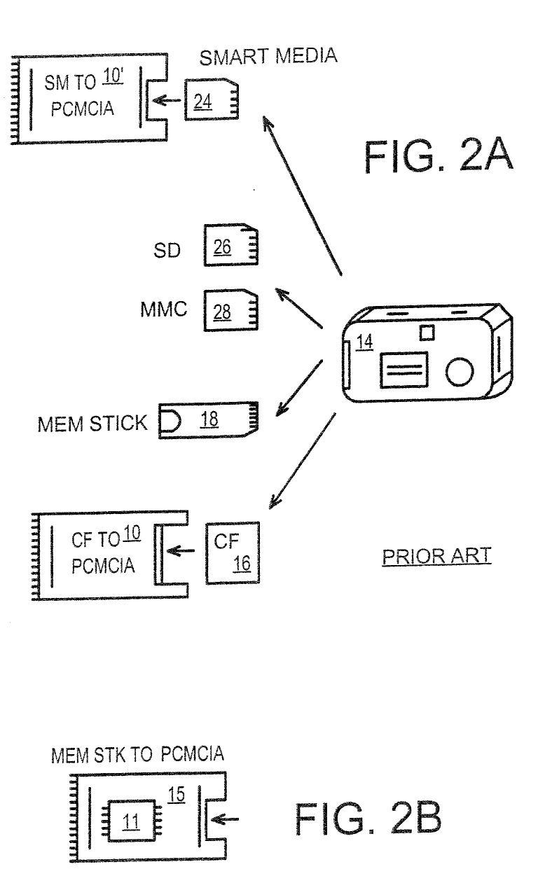

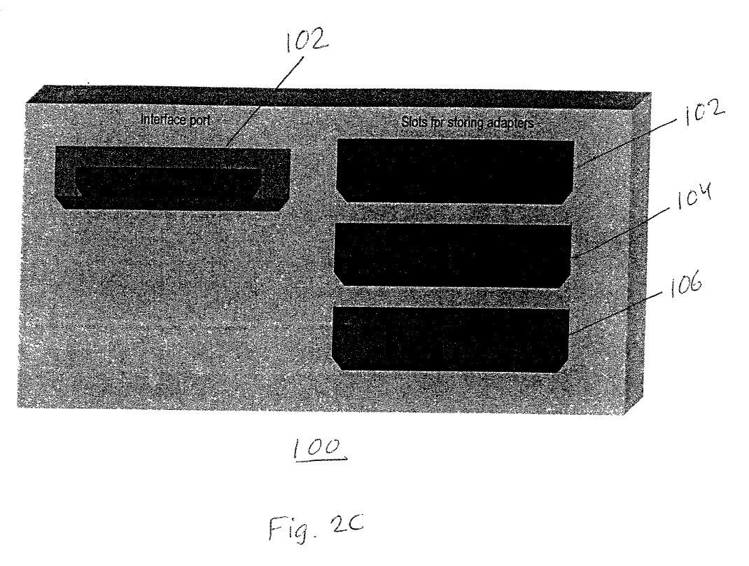

### DETAILED DESCRIPTION

The present invention relates generally to flash memory readers, and more particularly for interfacing several different types of flash memory cards to a device that includes a processor. The following description is presented to enable one of ordinary skill in the art to make and use the invention as provided in the context of a particular application and its requirements. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

In U.S. patent application Ser. No. 09/610,904, entitled “A Flash Toaster For Reading Several Types of Flash-Memory Cards With or Without A PC”, filed Jul. 6, 2000 and assigned to the assignee of the present application, a universal passive adapter is disclosed that can be constructed using the CompactFlash card form factor. A reader that reads CompactFlash cards can then read any of the other flash-memory cards that plug into the CompactFlash adapter. The adapters are simple, inexpensive passive adapters without a conversion chip.

In addition, the above-identified application discloses a pin mapping from the smaller flash-card formats to CompactFlash that allows for easy detection of the type of flash-memory card inserted into the adapter. Detection of the type of flash-memory card is thus performed automatically by electronic detection by the CompactFlash reader. The CompactFlash reader is modified to perform this card-type detection. Signal conversion such as serial-to-parallel is performed by the CompactFlash reader rather than by the adapter. Adapter costs are reduced while CompactFlash reader cost is increased only slightly. The CompactFlash reader can use a single CompactFlash slot to read multiple flash-card types, including SmartMedia, MultiMediaCard, Secure Digital, Memory Stick, and CompactFlash.

In another embodiment, the CompactFlash reader is somewhat larger, and has multiple slots. The adapter is not needed in this embodiment. Instead, a slot is provided for each of the flash-memory card formats−SmartMedia, MultiMediaCard, Secure Digital, Memory Stick, and CompactFlash. A PCMCIA can also be added. This CompactFlash reader can be connected to the PC by a USB cable, or it can be located within the PC chassis.

In a third embodiment, the CompactFlash reader is a stand-alone device that can operate without a PC. A removable disk media such as a R/W CD-ROM is included. The CompactFlash reader copies images from the flash-memory card to the removable disk media. A simple interface is used, such as having the user presses a button to initiate image transfer.

Although the above-identified CompactFlash reader operates effectively for its stated purpose, it cannot be utilized effectively in certain circumstances. The flash reader only allows for interface to USB on the output side and therefore cannot act as a translator between other interfaces such as IDE, CompactFlash or PCMCIA interfaces. In addition, the conventional method for storing the memory necessarily means that the some of the slots are inverted. A system and method in accordance with the present invention provides an active adapter that overcomes the above-identified problems.

Universal, Active Adapter

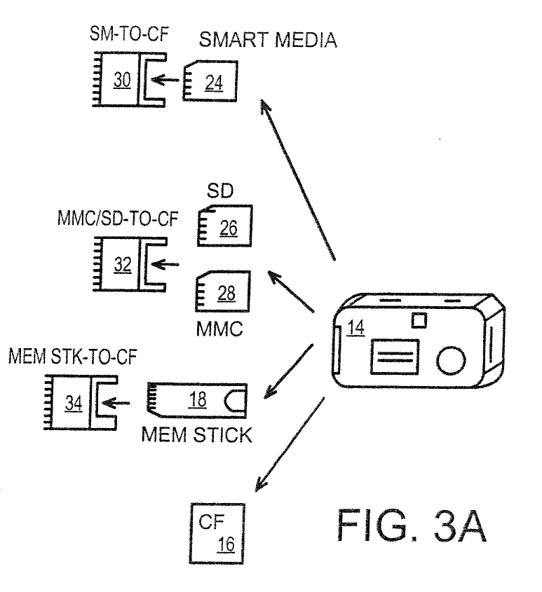

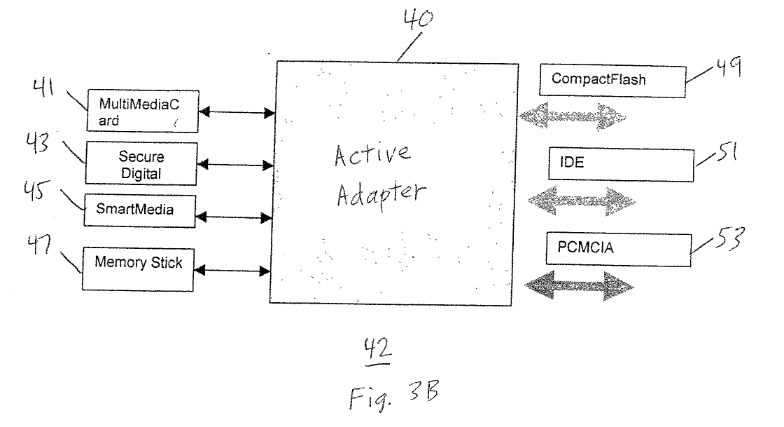

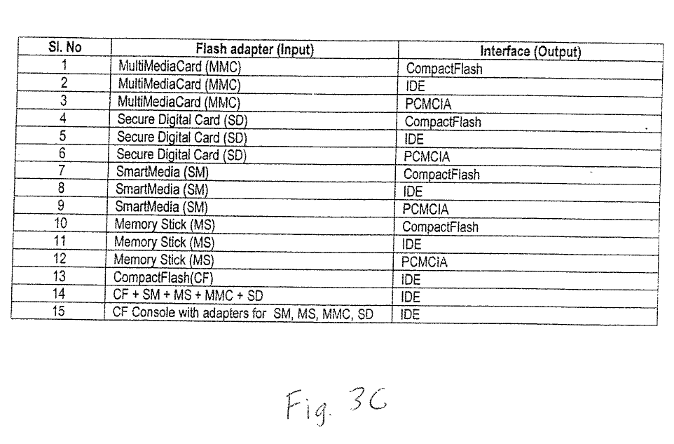

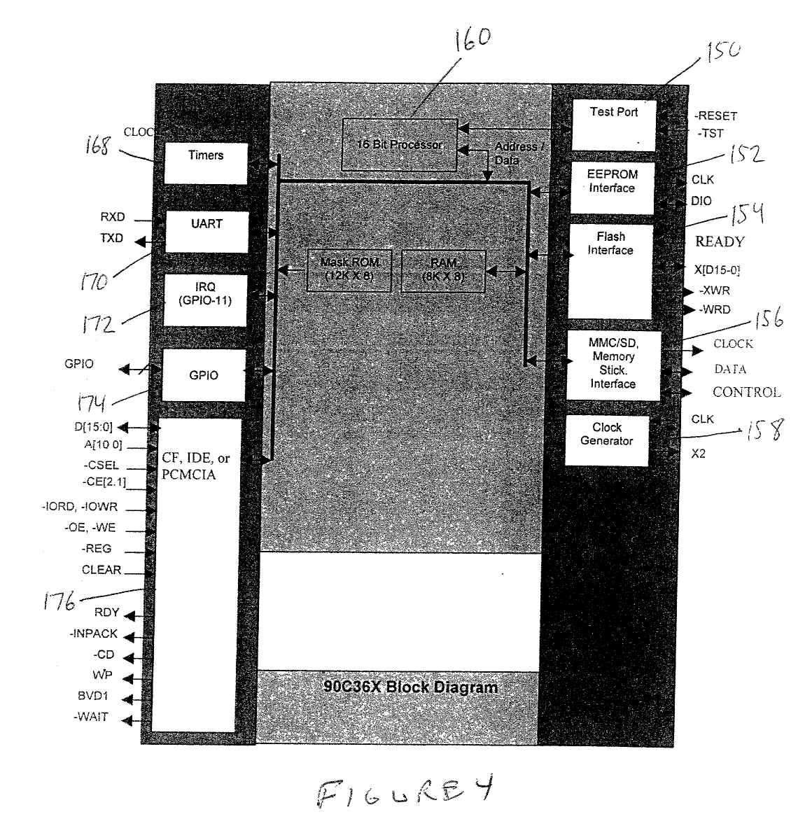

FIG. 3A shows a universal CompactFlash adapter that accepts SmartMedia, MultiMediaCard, Secure Digital, and Memory Stick flash-memory cards. Digital camera 14 stores images on flash memory that is in one of several card types. CompactFlash card 16 uses a 50-pin connector and transfers image data in a 16-bit parallel format.

SmartMedia card 24 is smaller flash-memory card with a 22-pin interface and transfers data in an 8-bit parallel format. SmartMedia adapter 30 converts the 22-pin SmartMedia interface to fit within the 50-pin CompactFlash interface. When SmartMedia card 24 is plugged into SmartMedia adapter 30, both can be plugged into a CompactFlash slot on a CompactFlash reader. Of course, ordinary CompactFlash readers will not be able to read SmartMedia card 24 since the CompactFlash reader requires special signal conversion.

MultiMediaCard 28 and Secure Digital card 26 are flash-memory cards with similar 9-pin interfaces. Serial data transfer is used through a single Data I/O pin. MMC/SD adapter 32 has an opening with a 9-pin connector to receive either MultiMediaCard 28 or Secure Digital card 26. Once MultiMediaCard 28 or Secure Digital card 26 is inserted into MMC/SD adapter 32, then MMC/SD adapter 32 can be inserted into a CompactFlash slot on a special CompactFlash reader. The CompactFlash reader then detects the card type and performs serial-to-parallel conversion.

Memory Stick 18 is also a flash-memory card with a 9-pin, serial-data interface, but is narrower and longer than MultiMediaCard 28 or Secure Digital card 26. Memory Stick adapter 34 has an opening with a 10-pin connector to receive Memory Stick 18. Once Memory Stick 18 is inserted, Memory Stick adapter 32 can itself be inserted into a CompactFlash slot on a special CompactFlash reader. The CompactFlash reader then detects the card type and performs serial-to-parallel conversion.

FIG. 3B shows a CompactFlash reader system 42 that reads SmartMedia 45, MultiMediaCard 41, Secure Digital 43, and Memory Stick flash-memory cards 47 on the input side and interfaces to CompactFlash 49, IDE 51 and PCMCIA 53 on an output side. In a preferred embodiment, the CompactFlash reader 42 has an opening or slot with a 50-pin connector that accepts a CompactFlash card 16. An active adapter chip 40 performs handshaking with a CompactFlash card 16 and performs data transfer. The active adapter chip 40 also controls the interface to the host PC, allowing image files to be transferred to the PC from any of the CompactFlash, IDE interface. Accordingly, the active adapter chip 40 in accordance with the present invention can read a variety of flash memory cards.

CompactFlash reader 42 can also read other kinds of flash-memory cards. For example, active adapter 40 allows Memory Stick to be read. Active adapter 40 has an opening that Memory Stick fits into, while active adapter 40 itself fits into 50-pin connector, since active adapter 40 has the same form factor as a CompactFlash card.

The SmartMedia card can also be read by CompactFlash reader 42, using active adapter 40. Likewise, MultiMediaCard or Secure Digital card can be read using active adapter 40. The active adapter chip 40 acts as translator between flash media and the plurality of interfaces. FIG. 3C is a table showing the translator inbetween the flash media and the plurality of interfaces. To describe the features of the active adapter chip 40, refer now to the following.

Active Adapter Chip 40

FIG. 4 is a block diagram of the active adapter 40 in accordance with the present invention. As before mentioned, the active adapter 40 is designed to connect a Memory Stick, SmartMedia, MMC or SD card to a CF slot. On an input side, the active adapter includes a test port 150, an EEPROM interface 152, a flash interface 154, a Memory Stick interface 156 and a clock generator 158. A processor 160 is coupled to all interfaces 152, 154 and 156 via a bus 161. A mask ROM 164 and RAM 166 are also coupled to the bus 161. On an output side, timers 168, UART 170, IRQ 172, GPIO 174 and a CF, IDE, PCMCIA interface 176 are coupled to the bus 161. The features of the active adapter chip 40 will be described hereinbelow.

Input Side

MMC/SD Memory Stick Interface 156

This interface provides support for MMC/SD and Memory Stick. The MultiMediaCard (MMC), Secure Digital Card (SD Card) and MemoryStick are serial access devices. These devices typically require in-bound/out-bound data to be appended with CRC information. The processor provides support in hardware to generate the CRC and to convert serial to parallel and parallel to serial bit streams. A programmable clock speed is provided to set the clock speed based on the media's capabilities.

EEPROM Interface 152

This port is used to read a serial EEPROM that contains programs for the internal processor.

CompactFlash/Smart Media Interface 154

This is the port for connecting a parallel device such as CompactFlash or SmartMedia cards. ECC generation and checking is provided for SmartMedia.

Clock Generator 158

This is the oscillator for the chip's internal clock.

Test Port 150

The test port supports 7200 to 115.2K baud. Is useful as a debug port and can also be used to access the EEPROM for reads/writes from the serial port.

Output Side

Timers 168

The timers are used for time dependent functions. For example, when power is turned on to a flash card there must be a delay before the card is accessed.

UART 170

The UART is a debug port that connects to a PC via a serial port.

GPIO 174 and IRQ 172

The GPIOs 174 and IRQ 172 are general-purpose input/output pins. They are used to control various Flash Card functions such as turning power on and off, detecting when a card is plugged in, detecting if a card is write protected, etc. For example, GPIO {11:10} can be used to generate an interrupt to the internal processor when there is change of state on one of these pins. This is used to detect the removal of a flash card.

CF/PCMCIA/IDE Interface 176

This interface is used to connect to a CompactFlash, PCMCIA, or IDE port.

Compact Flash is a subset of PCMCIA, the only real difference being the CompactFlash uses a smaller connector than PCMCIA. IDE is the standard disk connection inside a PC. CompactFlash/PCMCIA or IDE mode is selected when the chip is reset. If −OE is low during reset then IDE mode is selected.

Processing System (Processor 160, and ROM 164 and RAM 164)

Processor 160

The processor (preferably a 16-bit processor) along with the RAM and ROM controls the interface 176. The processor 160 detects the type of flash card plugged into the CF/Smart Media or MMC/SD/Memory Stick ports, configures itself accordingly and then translates commands received on the CF/PCMCIA/IDE interface 160 and passes them to the attached flash card.

Pin Mapping

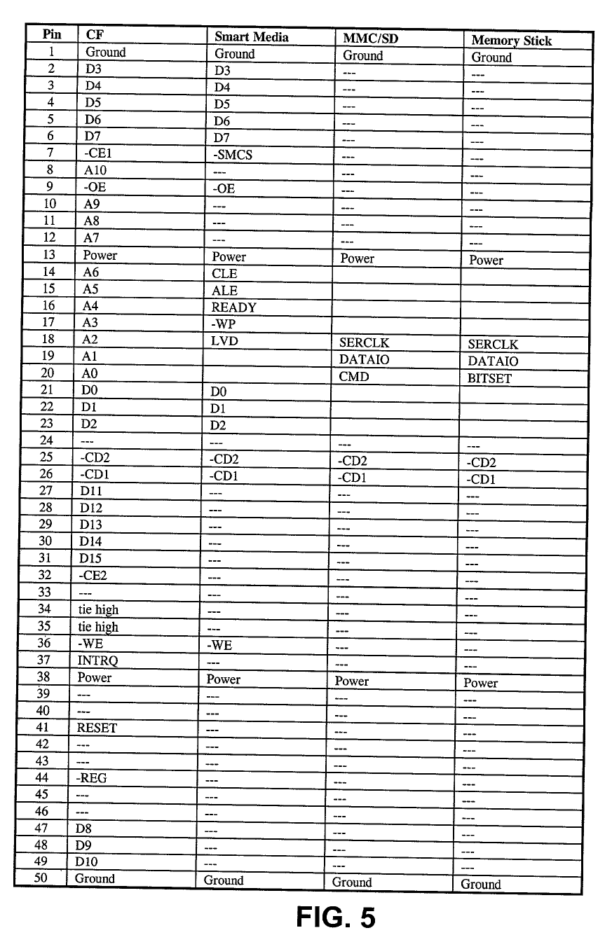

FIG. 5 is a table of pin mappings for the SmartMedia, MMC/SD, and Memory Stick to CompactFlash adapters. The pin numbers for the smaller interfaces for SmartMedia, MMC/SD, and Memory Stick are not shown but can be in any order or designation. The adapter connects the proper pin on the smaller interface to the CompactFlash pin number shown in FIG. 5. Simple wiring such as individual wires, flat cables, printed-circuit board (PCB), or wiring traces can be used.

The ground pins on the smaller interfaces are connected to CompactFlash pins 1 and 50. Power pins are connected to CompactFlash pins 13, 38. Pins 25, 26 are the card detect signals for CompactFlash, which the adapters connect to the card-detect signals on all smaller interfaces.

The CompactFlash connectors use pins 2-6, 21-23, 27-31, and 47-49 for the 16-bit parallel data bus to the CompactFlash card. Pins 8, 10-12, and 14-20 form a separate 11-bit address bus. The separate data and address buses provide for rapid random addressing of CompactFlash cards. Other control signals include pins 6, 32 chip enables, pin 9 output enable, pin 36 write enable, interrupt pin 37, reset pin 41, and register REG pin 44. REG pin 44 is the Attribute Memory Select, defined based on the CF mode of operation, i.e. PCMCIA I/O mode, IDE or PCMCIA Memory Mode. Several pins in the 50-pin interface are not connected.

The smaller SmartMedia interface also has a parallel data bus of 8 bits. These are mapped to pins 2-6, and 21-23 of the CompactFlash interface to match the CompactFlash D0:7 signals. While no separate address bus is provided, address and data are multiplexed. Control signals for latch enables, write enable and protect, output enable, and ready handshake are among the control signals. Output enable −OE and write enable −WE are mapped to the same function pins 9, 36 of the CompactFlash interface. The total number of pins in the SmartMedia interface is 22.

The Memory Stick and MMC/SD flash-memory-card interfaces are smaller still, since parallel data or address busses are not present. Instead, serial data transfers occur through serial data pin DATAIO, which is mapped to pin 19 (A1). Data is clocked in synchronization to clock SERCLK on pin 18. A command signal CMD or BITSET occupies pin 20 (A0). The MMC/SD and Memory Stick interfaces require only 6 pins plus power and ground.

Detection logic in the active converter chip 40 reads card-select pins CD0, CD1 to detect the presence of a flash-memory card. When a new card is present, detection logic then reads pins CE1, CE2 as inputs to determine the card type. The wiring inside the adapter and the card's behavior determines whether CE1, CE2 are pulled low or pulled high by the active adapter chip 40.

### ADVANTAGES OF THE INVENTION

An active adapter chip for flash-memory cards in accordance with the present invention accepts cards of several different formats. The active adapter chip accepts SmartMedia, MultiMediaCard, Secure Digital, and Memory Stick cards.

The active adapter chip is constructed using the CompactFlash card form factor. A reader that reads CompactFlash cards can then read any of the other flash-memory cards that plug into the CompactFlash adapter.

The disclosed pin mapping from the smaller flash-card formats to CompactFlash allows for easy detection of the type of flash-memory card inserted into the adapter. Detection of the type of flash-memory card is thus performed automatically by electronic detection by the CompactFlash reader. Signal conversion such as serial-to-parallel is performed by the CompactFlash reader rather than by the adapter. Adapter costs are reduced while CompactFlash reader cost is increased only slightly. The CompactFlash reader can use a single CompactFlash slot to read multiple flash-card types, including SmartMedia, MultiMediaCard, Secure Digital, Memory Stick, and CompactFlash and can also interface on the output side to a plurality of standards, including but not limited to CF, MMD/SC, IDE and PCMCIA standards.

### ALTERNATE EMBODIMENTS

The inventors contemplate several other embodiments. Different flash-card formats can be supported such as Smart Cards, and more or less than the four slots shown in the multi-card flash reader can be included. Any device that needs Control Bus, Clock, Data Bus and Address Bus can be designed to fit into these slots. Examples of such devices include (but are not limited to) DSL Modems, Fingerprint security devices, Miniature Hard disks, Digital Cameras, Video Cameras, printers and the like.

While the invention has been described as connecting to a personal computer PC host, the host may also be an Apple computer such as the iMAC or G3. The host may also be a SUN computer, or any host computer using a variety of interfaces. The invention can also apply to personal digital assistants (PDAs) such as by Palm Computer, printers or other handheld appliances, such as a cell phone with a variety of interface capabilities.

The term “CompactFlash reader” has been used for simplicity, since digital images are often read from the flash-memory card and then written to the PC. However, the CompactFlash reader is capable of reading files from the PC or from another flash-memory card and writing the file to the flash-memory card. Thus the CompactFlash reader is really a reader/writer.

In other alternate embodiments, the CompactFlash reader/multi-flash reader can be designed into a self-hosted appliance such as an MP3 player, printer, or a keyboard or a monitor or a stereo appliance. Additionally, the CompactFlash/multi-flash reader can also be designed into handheld data collection scanner devices. The CompactFlash/multi-flash reader can also be designed into personal digital assistant devices, pocket personal computer devices that use, for example, Microsoft Palm operating systems. The compact Flash/multi-flash reader can also be designed into hand terminal devices, personal communicator devices, advanced two-way pager devices, audio recorder and player devices.

The foregoing description of the embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A multi-flash-card reader comprising:
an active adapter chip for converting multiple flash-card interfaces to a plurality of output interfaces for a device;
wherein the multiple flash-card interfaces include a CompactFlash interface and smaller interfaces having fewer pins that the CompactFlash interface;
a CompactFlash connector, coupled to the active adapter chip, for receiving a CompactFlash card through a single slot in the single-slot multi-flash-card reader, the CompactFlash connector making electrical connection with the CompactFlash card for signals in the CompactFlash interface;
an adapter, having a physical shape to removably insert into the CompactFlash connector, the adapter having a mating CompactFlash connector that fits the CompactFlash connector, the adapter also having a smaller connector, the smaller connector for fitting to other flash-memory cards having the smaller interfaces; and
wiring means, in the adapter, connected between the smaller connector and the mating CompactFlash connector, for directly connecting signals from the smaller connector in the smaller interface with signals in the mating CompactFlash connector;
whereby the adapter allows the other flash-memory cards having the smaller interfaces to fit into the CompactFlash connector through the single slot to be read by the active adapter chip.

2. The multi-flash-card reader of claim 1 wherein the wiring means connects card select signals from all of the smaller interfaces to card select signals in the CompactFlash connector;
whereby the active adapter chip detects presence of CompactFlash and the other flash-memory cards having the smaller interfaces.

3. The multi-flash-card reader of claim 2 wherein the wiring means connects signals from the smaller interfaces to signals CE1, CE2 in the CompactFlash connector;
whereby the active adapter chip detects the type of flash-memory card inserted including CompactFlash and the other flash-memory cards having the smaller interfaces.

4. The multi-flash-card reader of claim 1 wherein the device comprises an intelligent device which interfaces to any type of flash media.

5. The multi-flash-card reader of claim 1 wherein the intelligent device includes any of a printer, scanner, cell phone or like device and the flash media includes any of a CompactFlash, Smart Media, Memory Stick, MicroDrive, MultiMediaCard and Secure Digital Card.

6. The multi-flash-card reader of claim 1 wherein the device comprises a host computer.

7. The multi-flash-card reader of claim 1 wherein the multiple flash card interfaces include any combination of: CompactFlash, SmartMedia interface, MMC/SD Memory Stick interface and EEPROM interface.

8. The multiple flash card interfaces of claim 7 wherein the plurality of output interfaces include any combination of: CompactFlash interface, PCMCIA interface, and IDE interface.

9. The multi-flash-card reader of claim 1 wherein the active adapter chip includes:
a plurality of flash card interfaces;
a plurality of output interfaces;
a bus coupled to the plurality of input interfaces and the plurality of output interfaces; and
a processor coupled to the bus for translating a signal from one of the plurality of flash card interfaces to a signal for one of a plurality of output interfaces.

10. The multi-flash-card reader of claim 9 wherein the multiple flash card interfaces include any combination of: CompactFlash, SmartMedia interface, MMC/SD Memory Stick interface and EEPROM interface.

11. The multiple flash card interfaces of claim 10 wherein the plurality of output interfaces include any combination of: CompactFlash interface, PCMCIA interface, and IDE interface.

12. A multi-flash-card reader comprising:
an active adapter chip, coupled to the host connection, for converting signals from flash-memory cards to read data from the flash-memory cards for transfer to a device;
a first connector, coupled to the converter chip, for accepting a CompactFlash card inserted into a first slot for the first connector, the first connector having a parallel-data bus and an address bus and control signals for controlling parallel data transfer from the CompactFlash card to the active adapter chip;
a second connector, coupled to the active adapter chip, for accepting a SmartMedia card inserted into a second slot for the second connector, the second connector having a parallel-data bus and control signals for controlling parallel data transfer from the SmartMedia card to the active adapter chip; and
a third connector, coupled to the active adapter chip, for accepting a MultiMediaCard or Secure Digital card inserted into a third slot for the third connector, the third connector having a serial-data pin and a clock pin for controlling serial data transfer from the MMC card (SD Card) to the active adapter chip;
wherein the active adapter chip controls parallel data and address transfer for the CompactFlash card, parallel data transfer for the SmartMedia card, and serial data transfer for the MMC card,
whereby multiple flash-memory cards can be read by the multi-flash-card reader using the active adapter chip.

13. The multi-flash-card reader of claim 12 wherein the host connection is through an external cable to the device;
wherein the multi-flash-card reader is in an external housing separate from the device,
whereby the multi-flash-card reader is external.

14. The multi-flash-card reader of claim 12 wherein the device comprises a printer.

15. The multi-flash-card reader of claim 12 wherein the device comprises a host computer.

16. The multi-flash-card reader of claim 12 wherein the multiple flash card interfaces include any combination of: CompactFlash interface, SmartMedia interface, MMC/SD Memory Stick interface and EEPROM interface.

17. The multiple flash card interfaces of claim 16 wherein the plurality of output interfaces include any combination of: CompactFlash interface, PCMCIA interface, and IDE interface.

18. The multi-flash-card reader of claim 12 wherein the active adapter chip includes:
a plurality of flash card interfaces;
a plurality of output interfaces;
a bus coupled to the plurality of input interfaces and the plurality of output interfaces; and
a processor coupled to the bus for translating a signal from one of the plurality of flash card interfaces to a signal for one of a plurality of output interfaces.

19. The multi-flash-card reader of claim 18 wherein the multiple flash card interfaces include any combination of: CompactFlash interface, SmartMedia interface, MMC/SD Memory Stick interface and EEPROM interface.

20. The multiple flash card interfaces of claim 19 wherein the plurality of output interfaces include any combination of: CompactFlash interface, PCMCIA interface, and IDE interface.

21. An active adapter chip comprising:
a plurality of flash card interfaces; wherein the plurality of flash card interfaces include any combination of: CompactFlash interface, SmartMedia interface, MMC/SD Memory Stick interface and EEPROM interface;
a plurality of output interfaces; wherein the plurality of output interfaces include any combination of: CompactFlash interface, PCMCIA interface, and IDE interface;
a bus coupled to the plurality of flash card interfaces; and the plurality of output interfaces; and
a processor coupled to the bus for translating a signal from one of the plurality of flash card interfaces to a signal for one of a plurality of output interfaces.

22. The active adapter chip of claim 21 which includes memory coupled between the flash card interfaces and the plurality of output interfaces.

23. The active adapter chip of claim 22 which includes a test port in communication with the processor.

24. The active adapter chip of claim 23 which includes timers, a UART and a general purpose input/output communicates with the bus.
